(19) United States
(12) Patent Application Publication
(10) Pub. No.: US 2024/0162372 A1
(43) Pub. Date: May 16, 2024

(54) LIGHT-EMITTING DEVICE AND LIGHT-EMITTING APPARATUS

(71) Applicant: TIANJIN SANAN OPTOELECTRONICS CO., LTD., Tianjin (CN)

(72) Inventors: Weihuan LI, Tianjin (CN); Jinghua CHEN, Xiamen (CN); Huan-Shao KUO, Tianjin (CN); Yu-Ren PENG, Tianjin (CN); Dongpo CHEN, Tianjin (CN); Chia-Hung CHANG, Xiamen (CN)

(21) Appl. No.: 18/505,845

(22) Filed: Nov. 9, 2023

(30) Foreign Application Priority Data
Nov. 14, 2022 (CN) 202211419345.1

(51) Int. Cl. H01L 33/02; H01L 33/00; H01L 33/06; H01L 33/14; H01L 33/22; H01L 33/30; H01L 33/40

(52) U.S. Cl. CPC H01L 33/025; H01L 33/0093; H01L 33/06; H01L 33/14; H01L 33/22; H01L 33/30; H01L 33/405; H01L 2933/0016

(57) ABSTRACT

A light-emitting device includes a semiconductor epitaxial structure that has a first surface and a second surface opposite to the first surface, and that includes a first semiconductor layer, an active layer, and a second semiconductor layer sequentially disposed in such order in a direction from the first surface to the second surface. The active layer includes well layers and barrier layers that are alternately stacked. The active layer has an upper surface that is adjacent to the second semiconductor layer, and a lower surface that is opposite to the upper surface. The first semiconductor layer is doped with an n-type dopant, which has a first concentration of 5E17/cm³ at a first point in the first semiconductor layer. The first point of the first semiconductor layer and the lower surface of the active layer have a first distance therebetween. The first distance ranges from 150 nm to 500 nm.

### CROSS-REFERENCE TO RELATED APPLICATION

This application claims priority to Chinese Invention Patent Application No. 202211419345.1, filed on Nov. 14, 2022, which is incorporated herein by reference in its entirety.

### FIELD

The disclosure relates to a semiconductor device, and more particularly to a light-emitting device.

### BACKGROUND

Light-emitting devices (LEDs) are considered to be one of the light sources having the most potential as they offer advantages including high luminous intensity, high efficiency, small size, and long lifespan. In recent years, LEDs have been widely applied in various fields, such as lighting, signal display, backlight, automotive light, big screen display, etc., all of which ask for a higher level of luminous intensity and luminous efficiency of the LEDs.

A light-emitting device has a first semiconductor layer and a second semiconductor layer respectively doped with an n-type dopant and a p-type dopant to respectively provide electrons and holes, which are recombined in an active layer for light emitting. To increase the electrons and the holes, each of the first semiconductor layer and the second semiconductor layer needs to have a higher doping concentration. Due to diffusion and memory effect of the n-type dopant and the p-type dopant, the n-type dopant and the p-type dopant are more likely to diffuse into the active layer, thereby affecting lattice quality of the active layer and luminous intensity of the light-emitting device.

### SUMMARY

Therefore, an object of the disclosure is to provide a light-emitting device that can alleviate at least one of the drawbacks of the prior art.

According to the disclosure, the light-emitting device includes a semiconductor epitaxial structure that has a first surface and a second surface opposite to the first surface, and that includes a first semiconductor layer, an active layer, and a second semiconductor layer sequentially disposed in such order in a direction from the first surface to the second surface.

The active layer includes well layers and barrier layers that are alternately stacked. The active layer has an upper surface that is adjacent to the second semiconductor layer, and a lower surface that is opposite to the upper surface.

The first semiconductor layer is doped with an n-type dopant. The n-type dopant has a first concentration of 5E17/cm³ at a first point in the first semiconductor layer, and the first point of the first semiconductor layer and the lower surface of the active layer have a first distance therebetween. The first distance ranges from 150 nm to 500 nm.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating an embodiment of a semiconductor epitaxial structure according to the disclosure.

FIG. 2 is a schematic view illustrating an embodiment of the semiconductor epitaxial structure according to the disclosure.

FIG. 3 is a graph illustrating a relationship between concentration or ion intensity and depth in a region of the semiconductor epitaxial structure shown in FIG. 1.

FIG. 4 is a graph illustrating a relationship between concentration or ion intensity and depth in another region of the semiconductor epitaxial structure shown in FIG. 1.

FIG. 5 is a graph illustrating a relationship between concentration or ion intensity and depth in a region of an embodiment of the semiconductor epitaxial structure according to the disclosure.

FIG. 6 is a schematic view illustrating an embodiment of a light-emitting device according to the disclosure.

FIG. 7 is a schematic view illustrating formation of a second electrode and bonding of a semiconductor epitaxial structure to a temporary substrate during manufacturing of the light-emitting device as shown in FIG. 6.

FIG. 8 is a schematic view illustrating removal of a growth substrate and bonding of the semiconductor epitaxial structure to a substrate during manufacturing of the light-emitting device as shown in FIG. 6.

FIG. 9 is a schematic view illustrating removal of the temporary substrate and roughening of a surface of the semiconductor epitaxial structure during manufacturing of the light-emitting device as shown in FIG. 6.

FIG. 10 is a schematic view illustrating an embodiment of the light-emitting device according to the disclosure.

FIG. 11 is a schematic view illustrating transfer of the semiconductor epitaxial structure onto the substrate and removal of the growth substrate during manufacturing of the light-emitting device as shown in FIG. 10.

FIG. 12 is a schematic view illustrating formations of a first electrode and a second electrode during manufacturing of the light-emitting device as shown in FIG. 10.

FIG. 13 is a schematic view illustrating an embodiment of the light-emitting device according to the disclosure.

FIG. 14 is a schematic view illustrating an embodiment of a light-emitting apparatus according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

The composition of each layer in a light-emitting device of the present disclosure and dopants may be analyzed by any suitable means, such as by a secondary ion mass spectrometer (SIMS). A thickness of each layer may be analyzed by any suitable means, such as by a transmission electron microscope (TEM) or a scanning electron microscope (SEM). Graph(s) from the transmission electron microscope (TEM) or the scanning electron microscope (SEM) may be used with graph(s) from the SIMS to determine concentrations at positions/points in a semiconductor epitaxial structure.

An embodiment of the light-emitting device is provided. By adjusting a distance between a semiconductor layer, which has a high doping concentration (e.g., a concentration of 5E17/cm³ or more), and an active layer, diffusion of the dopants into the active layer may be controlled, lattice quality of the active layer may be improved, and photoelectricity performance of the light-emitting device may be improved.

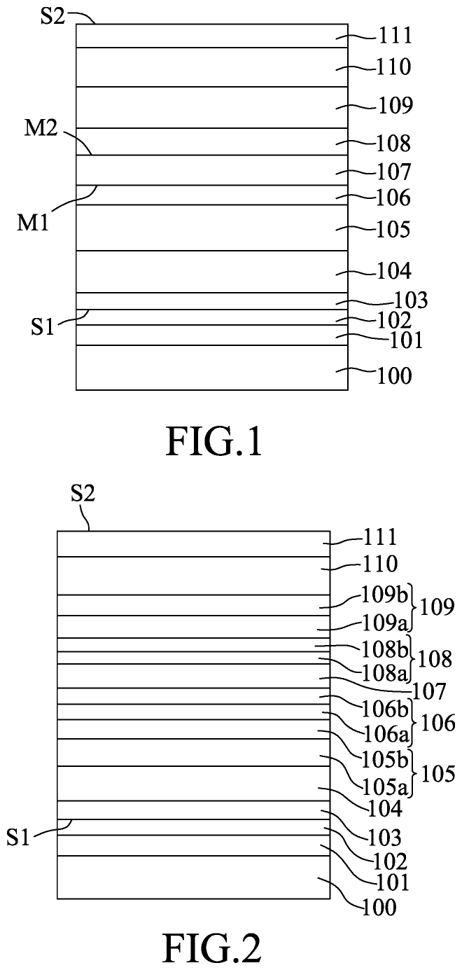

FIGS. 1 and 2 are schematic views illustrating embodiments of a semiconductor epitaxial structure according to the disclosure and a variation thereof. The semiconductor epitaxial structure is formed on a growth substrate 100. The semiconductor epitaxial structure has a first surface (S1) and a second surface (S2) opposite to the first surface (S1), and includes a first current spreading layer 104, a first cladding layer 105, a first spacing layer 106, an active layer 107, a second spacing layer 108, a second cladding layer 109, a second current spreading layer 110, and a second ohmic contact layer 111 sequentially stacked in such order on the growth substrate 100 in a direction from the first surface (S1) to the second surface (S2).

Specifically, referring to FIG. 1, the growth substrate 100 may be made of, but is not limited to, GaAs, GaP, InP, etc. In this embodiment, the growth substrate 100 is made of GaAs. In some embodiments, a buffer layer 101, an etch stop layer 102, and a first ohmic contact layer 103 are also sequentially disposed between the growth substrate 100 and the first current spreading layer 104. Because lattice quality of the buffer layer 101 is better than that of the growth substrate 100, forming the buffer layer 101 on the growth substrate 100 may alleviate adverse effects of lattice defects of the growth substrate 100 on the semiconductor epitaxial structure. The etch stop layer 102 serves to stop etching in later procedures. In certain embodiments, the etch stop layer 102 is an n-type etch stop layer made of n-type GaInP. To facilitate a later removal of the growth substrate 100, the etch stop layer 102 may have a thickness that is greater than 0 nm and no greater than 500 nm. In some embodiments, the thickness of the etch stop layer 102 is no greater than 200 nm. In some embodiments, the first ohmic contact layer 103 is made of a GaAs material, and has a thickness ranging from 10 nm to 100 nm and a doping concentration ranging from 1E18/cm³ to 10E18/cm³. In some embodiments, the doping concentration of the first ohmic contact layer 103 is 2E18/cm³ so as to achieve a better ohmic contact.

The semiconductor epitaxial structure may be formed on the growth substrate 100 by using methods such as physical vapor deposition (PVD), chemical vapor deposition (CVD), epitaxy growth technology, atomic layer deposition (ALD), etc. The semiconductor epitaxial structure may contain a semiconductor material that generates light, such as ultra-violet light, blue light, green light, yellow light, red light, and infrared light. Specifically, the semiconductor material of the semiconductor epitaxial structure may be a material that generates light having a wavelength ranging from 200 nm to 950 nm, such as a nitride material. In certain embodiments, the semiconductor epitaxial structure may be a GaN-based laminate which may be doped with aluminum, indium, etc. and may generate light having a wavelength ranging from 200 nm to 550 nm. In other embodiments, the semiconductor epitaxial structure is an AlGaInP-based laminate or an AlGaAs-based laminate that generates light having a wavelength ranging from 550 nm to 950 nm.

The semiconductor epitaxial structure includes a first semiconductor layer, the active layer 107, and a second semiconductor layer sequentially disposed in such order in a direction away from the growth substrate 100 (i.e., in a direction from the first surface (S1) to the second surface (S2)). The first semiconductor layer and the second semiconductor layer may be respectively an n-type doped semiconductor layer and a p-type doped semiconductor layer to provide electrons and holes, respectively. The n-type doped semiconductor layer may be doped with an n-type dopant such as Si, Ge, Te, or Sn, and the p-type doped semiconductor layer may be doped with a p-type dopant such as Mg, Zn, Ca, Sr, or Ba. When the first semiconductor layer is the n-type doped semiconductor layer, the second semiconductor layer is the p-type doped semiconductor layer; when the first semiconductor layer is the p-type doped semiconductor layer, the second semiconductor layer is the n-type doped semiconductor layer. The first semiconductor layer, the active layer 107, and the second semiconductor layer may be made of materials such as aluminum gallium indium nitride, gallium nitride, aluminum gallium nitride, aluminum indium phosphorus, aluminum gallium indium phosphorus, gallium arsenide, aluminum gallium arsenic, etc. In this embodiment, the first semiconductor layer is the n-type doped semiconductor layer, and the second type semiconductor layer is the p-type doped semiconductor layer.

The first semiconductor layer includes the first cladding layer 105 that provides one of the electrons and the holes for the active layer 107, and the second semiconductor layer includes the second cladding layer 109 that provides the other of the electrons and the holes for the active layer 107. To enhance uniformity of current spreading, the first semiconductor layer also includes the first current spreading layer 104, and the second semiconductor layer also includes the second current spreading layer 110.

The first current spreading layer 104 serves to spread current, and its ability of current spreading depends on its thickness. The first current spreading layer 104 may have a material that is represented by Al_{y1}Ga_{1-y1}InP, a thickness that ranges from 2500 nm to 4000 nm, and an n-type doping concentration that ranges from 4E17/cm³ to 4E18/cm³. A common n-type dopant include Si or Te, and does not exclude other equivalent elements. In this embodiment, the n-type dopant contains Te.

To prevent dopants in the first cladding layer 105 from diffusing into the active layer 107 and affecting the lattice quality of the active layer 107, thereby affecting luminous intensity and efficiency of a light-emitting device containing the semiconductor epitaxial structure, in this embodiment, the first spacing layer 106 is disposed between the first cladding layer 105 and the active layer 107 so as to prevent the dopants in the first cladding layer 105 from diffusing into the active layer 107, thereby increasing the luminous efficiency of the light-emitting device. To provide enough electrons, the first cladding layer 105 needs to reach a doping concentration above a certain value. In this embodiment, the doping concentration of the first cladding layer 105 is no smaller than 5E17/cm³. To control diffusion of the n-type dopant in the first semiconductor layer into the active layer 107, in this embodiment, a first distance (d1) between a first point (A) of the first semiconductor layer and a lower surface (M1) of the active layer 107 is adjusted. The first point (A) in the first semiconductor layer is where the n-type dopant has a doping concentration of 5E17/cm³. The first distance (d1) ranges from 150 nm to 500 nm. By increasing the first distance (d1), the diffusion of the n-type dopant into the active layer 107 may be effectively controlled and the lattice quality of the active layer 107 may be improved, thereby improving photoelectric performance of the light-emitting device.

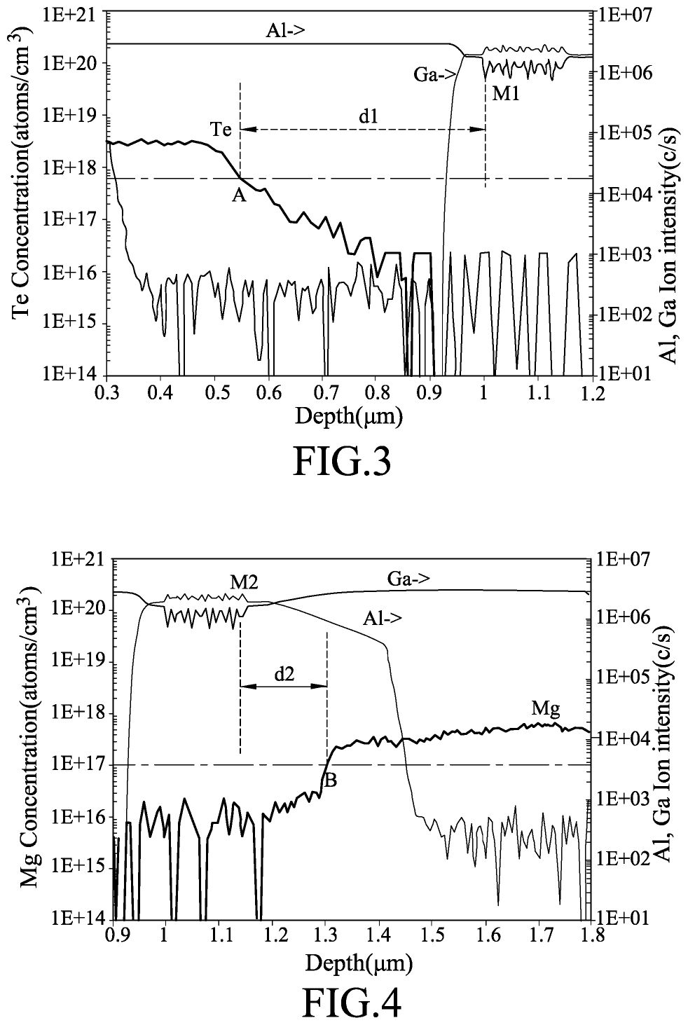

FIG. 3 is a graph illustrating a relationship between concentration or ion intensity and depth (i.e., starting from the second surface (S2) toward the first surface (S1) of the semiconductor epitaxial structure) in a region of the semiconductor epitaxial structure shown in FIG. 1. FIG. 3 was obtained from a secondary ion mass spectrometer. The doping concentration of the n-type dopant, and relative ion intensity of Ga and Al can be seen from FIG. 3. In this embodiment, the n-type dopant is Te, and the active layer 107 has an upper surface (M2) that is adjacent to the second semiconductor layer and the lower surface (M1) that is opposite to the upper surface (M2). As shown in FIG. 3, aluminum has a relative ionic concentration profile, and the lower surface (M1) of the active layer 107 corresponds to a position of a first valley of the relative ionic concentration profile of aluminum. The semiconductor epitaxial structure includes the n-type dopant, Te, which has the concentration of 5E17/cm³ at the first point (A). In this embodiment, the first point (A) is located in the first cladding layer 105. The distance from the first point (A) to the lower surface (M1) of the active layer 107 is defined to be the first distance (d1). Due to a strong memory effect of Te, in the present embodiment, when the n-type dopant is Te, the first distance (d1) ranges from 200 nm to 500 nm. In other embodiments, the first distance (d1) ranges from 220 nm to 400 nm, or 250 nm to 400 nm. In such range, the diffusion of the dopant, Te, into the active layer 107 may be controlled or prevented, and the lattice quality of the active layer 107 may be improved, thereby improving the luminous intensity and efficiency of the light-emitting device.

In some embodiments, as shown in FIG. 2, the first cladding layer 105 includes a first sublayer 105a and a second sublayer 105b. The first sublayer 105a has a thickness that is one-third to two-thirds of a thickness of the first cladding layer 105. The first sublayer 105a has a doping concentration greater than 8E17/cm³, and the second sublayer 105b has a doping concentration that decreases in the direction from the first surface (S1) to the second surface (S2) of the semiconductor epitaxial structure. The first cladding layer 105 includes a material that is represented by Alₓ₁Ga₁₋ₓ₁InP, where 0.4≤x1<1. In some embodiments, the first cladding layer 105 is made of AlInP. Since intrinsic wavelength of AlInP is 490 nm, light absorption of the first cladding layer 105 may be effectively reduced, thereby improving the luminous intensity of the light-emitting device.

To further prevent the n-type dopant from diffusing into the active layer 107, a first spacing layer 106 may be disposed between the first cladding layer 105 and the active layer 107. The first spacing layer 106 may be unintentionally doped, and may have a doping concentration smaller than 1E17/cm³. The first spacing layer 106 may have a single-layered or a multilayered structure. In some embodiments, the first spacing layer 106 has a multilayered structure, and the first spacing layer 106 includes a material that is represented by Alₐ₁Ga₁₋ₐ₁InP, and a1 may range from 0.3 to 1. The first spacing layer 106 includes a first sublayer 106a and a second sublayer 106b. An aluminum content of the first sublayer 106a decreases in a direction from the first cladding layer 105 to the active layer 107. An aluminum content of the second sublayer 106b may be constant. That is to say, the first spacing layer 106 may have an aluminum content that first decreases and then remains constant in the direction from the first surface (S1) to the second surface (S2) of the semiconductor epitaxial structure. The aluminum content of the first sublayer 106a may decrease in a linear manner or a stepwise manner in the direction from the first cladding layer 105 to the active layer 107. The aforementioned variation of the aluminum content in the first sublayer 106a of the first spacing layer 106 may reduce lattice difference between the first cladding layer 105 and the first spacing layer 106, thereby improving the lattice quality of the active layer 107 and the luminous intensity of the light-emitting device.

The active layer 107 is a region where the electrons and the holes recombine. Depending on a wavelength of light to be emitted by the active layer 107, materials for the active layer 107 may vary. The active layer 107 may have a single quantum well or a multiple quantum well structure. In this embodiment, the active layer 107 has a multiple quantum well structure having multiple layer units. The active layer 107 includes well layers and barrier layers that are alternately stacked, and each of the barrier layers has a greater band gap than that of the well layer. By adjusting a composition of the semiconductor material of the active layer 107, the active layer 107 may emit a pre-determined wavelength of light. The semiconductor material of the active layer 107, such as aluminum gallium indium phosphorus, aluminum gallium arsenic, exhibits electroluminescence property. In some embodiments, the semiconductor material of the active layer 107 includes aluminum gallium indium phosphorus which may be in a single quantum well or a multiple quantum well structure. In this embodiment, the active layer 107 is made of an AlGaInP-based or a GaAs-based material, and the active layer 107 emits light having a wavelength ranging from 550 nm to 950 nm.

Each of the well layers and a corresponding one of the barrier layers that is adjacent to the each of the well layers constitute a layer unit, and a number of layer unit ranges from 2 to 100. Each of the well layers includes a material that is represented by Alₓ₃Ga₁₋ₓ₃InP, and each of the barrier layers includes a material that is represented by Al_{y}Ga_{1-y}InP, where 0≤x3<y≤1. Each of the wells layer has a thickness ranging from 5 nm to 25 nm, and each of the barrier layers has a thickness ranging from 5 nm to 25 nm. Each of the barrier layers has an aluminum content (y) that ranges from 0.3 to 0.85.

The second semiconductor layer above the upper surface (M2) of the active layer 107 has the p-type dopant such as Mg, Zn, Ca, Sr or Ba. In this embodiment, the p-type dopant is Mg and has a doping concentration profile. To provide enough holes, the second cladding layer 109 needs to reach a doping concentration above a certain value. In this embodiment, the doping concentration of the second cladding layer 109 is no smaller than 1E17/cm³. To control diffusion of the p-type dopant in the second semiconductor layer into the active layer 107, in this embodiment, a second distance (d2) between a second point (B) of the second semiconductor layer and the upper surface (M2) of the active layer 107 is adjusted. The second point (B) in the second semiconductor layer is where the p-type dopant has a doping concentration of 1E17/cm³. By adjusting the second distance (d2), the diffusion of the p-type dopant into the active layer 107 may be effectively controlled and the lattice quality of the active layer 107 may be improved, thereby improving the photoelectric performance of the light-emitting device. In this embodiment, the second distance (d2) ranges from 40 nm to 400 nm. In other embodiments, the second distance (d2) ranges from 60 nm or 80 nm to 400 nm.

FIG. 4 is a graph illustrating a relationship between concentration or ion intensity and depth in another region of the semiconductor epitaxial structure shown in FIG. 1. FIG. 4 was obtained from a secondary ion mass spectrometer. The doping concentration of the p-type dopant and the relative ion intensity of Ga and Al can be seen from FIG. 4. In this embodiment, the p-type dopant is Mg, and the active layer 107 has the upper surface (M2) that is adjacent to the second semiconductor layer. The upper surface (M2) of the active layer 107 corresponds to a position of a last valley of the concentration profile of aluminum in FIG. 4. The semiconductor epitaxial structure includes the p-type dopant disposed above the upper surface (M2) of the active layer 107 (i.e., in the second semiconductor layer). The p-type dopant has a concentration of 1E17/cm³ at the second point (B) in the second semiconductor layer. The distance from the second point (B) of the second semiconductor layer to the upper surface (M2) of the active layer 107 is defined to be the second distance (d2). Due to a strong memory effect of Mg, in the present embodiment, when the p-type dopant is Mg, the second distance (d2) ranges from 40 nm to 400 nm. In another embodiment, the second distance (d2) ranges from 60 nm to 400 nm, or 80 nm to 400 nm, so that the diffusion of the p-type dopant into the active layer 107 may be effectively controlled or prevented, and the lattice quality of the active layer 107 may be improved, thereby improving the luminous intensity and efficiency of the light-emitting device. In this embodiment, the second point (B) is located in the second spacing layer 108.

To control the diffusion of the p-type dopant into the active layer 107, the second spacing layer 108 is disposed between the active layer 107 and the second cladding layer 109. In this embodiment, the second spacing layer 108 includes a material that is represented by Al_{b2}Ga_{1-b2}InP, has a thickness ranging from 40 nm to 400 nm, and has a doping concentration smaller than 1E17/cm³. An aluminum content (b2) of the second spacing layer 108 ranges from 0.3 to 1. The second spacing layer 108 is disposed between the active layer 107 and the second cladding layer 109, and may be unintentionally doped so as to effectively control the diffusion of the p-type dopant into the active layer 107, thereby improving the lattice quality of the active layer 107 and the luminous intensity of the light-emitting device.

The second spacing layer 108 may have a single-layered structure or a multilayered structure. In some embodiments, the second spacing layer 108 has a single-layered structure that includes a material of that is represented by Al_{b2}Ga_{1-b2}InP and that has a constant aluminum content. In some embodiments, the second spacing layer 108 has a multilayered structure, and includes a first sublayer 108a and a second sublayer 108b disposed in such order in a direction from the active layer 107 to the second cladding layer 109. In this embodiment, an aluminum content of the first sublayer 108a remains constant, while an aluminum content of the second sublayer 108b gradually increases in the direction from the active layer 107 to the second cladding layer 109. In this embodiment, the aluminum content of the second sublayer 108b gradually increases from a content which is the same as that of the first sublayer 108a to a content which is the same as that of the second cladding layer 109. The aluminum content of the second sublayer 108b may increase in a linear manner or a stepwise manner in the direction from the active layer 107 to the second cladding layer 109. In this embodiment, the gradual increase in the aluminum content of the second spacing layer 108 may reduce lattice difference between the second spacing layer 108 and the second cladding layer 109, thereby improving the lattice quality of the second cladding layer 109 and the luminous intensity of the light-emitting device.

The second semiconductor layer includes the second cladding layer 109, the second current spreading layer 110, and the second ohmic contact layer 111. The second cladding layer 109 provides the holes for the active layer 107. In this embodiment, the second cladding layer 109 includes a material that is represented by Al_{z}Ga_{1-z}InP material. The second cladding layer 109 may have a single-layered structure or a multilayered structure. In some embodiments, the second cladding layer 109 has a single-layered structure, and the aluminum content of the second cladding layer 109 is constant. In some embodiments, the second cladding layer 109 is made of AlInP, which may reduce light absorption of the second cladding layer 109 and improves the luminous intensity of the light-emitting device. In certain embodiments, the second cladding layer 109 has a multilayered structure, and includes at least a first sublayer 109a and a second sublayer 109b sequentially stacked in the direction from the first surface (S1) to the second surface (S2) of the semiconductor epitaxial structure. In this embodiment, an aluminum content of the first sublayer 109a of the second cladding layer 109 gradually increases in the direction from the first surface (S1) to the second surface (S2) of the semiconductor epitaxial structure, while an aluminum content of the second sublayer 109b remains constant. In certain embodiments, the second sublayer 109b is made of AlInP, which may reduce light absorption of the second cladding layer 109 and improve the luminous intensity of the light-emitting device.

The second current spreading layer 110 serves to spread current, and its ability of current spreading depends on its thickness. In this embodiment, the thickness may vary according to size of the light-emitting device. In certain embodiments, the second current spreading layer 110 has a thickness that ranges from 300 nm to 12000 nm. In this embodiment, the thickness of the second current spreading layer 110 ranges from 500 nm to 10000 nm. In this embodiment, the second current spreading layer 110 is made of GaP and has a p-type doping concentration that ranges from 6E17/cm³ to 2E18/cm³. A common p-type dopant includes Mg and does not exclude other equivalent elements.

The second ohmic contact layer 111 forms an ohmic contact with a second electrode 204, may be made of GaP, and has a doping concentration of 1E19/cm³. In some embodiments, the doping concentration of the second ohmic contact layer 111 is greater than 5E19/cm³ so as to achieve a better ohmic contact. The second ohmic contact layer 109 has a thickness that may range from 40 nm to 150 nm. In this embodiment, the thickness of the second ohmic contact layer 111 is 60 nm.

In this embodiment, by adjusting the first distance (d1) between the first point (A) in the first semiconductor layer, which has the n-type doping concentration of 5E17/cm³, and the lower surface (M1) of the active layer 107, the diffusion of the n-type dopant into the active layer 107 may be controlled so as to improve the lattice quality of the active layer 107, thereby improving the photoelectric performance of the light-emitting device. By further adjusting the second distance (d2) between the second point (B) in the second semiconductor layer, which has the p-type doping concentration of 1E17/cm³, and the upper surface (M2) of the active layer 107, the diffusion of the p-type dopant into the active layer 107 may be controlled so as to improve the lattice quality of the active layer 107, thereby improving the photoelectric performance of the light-emitting device.

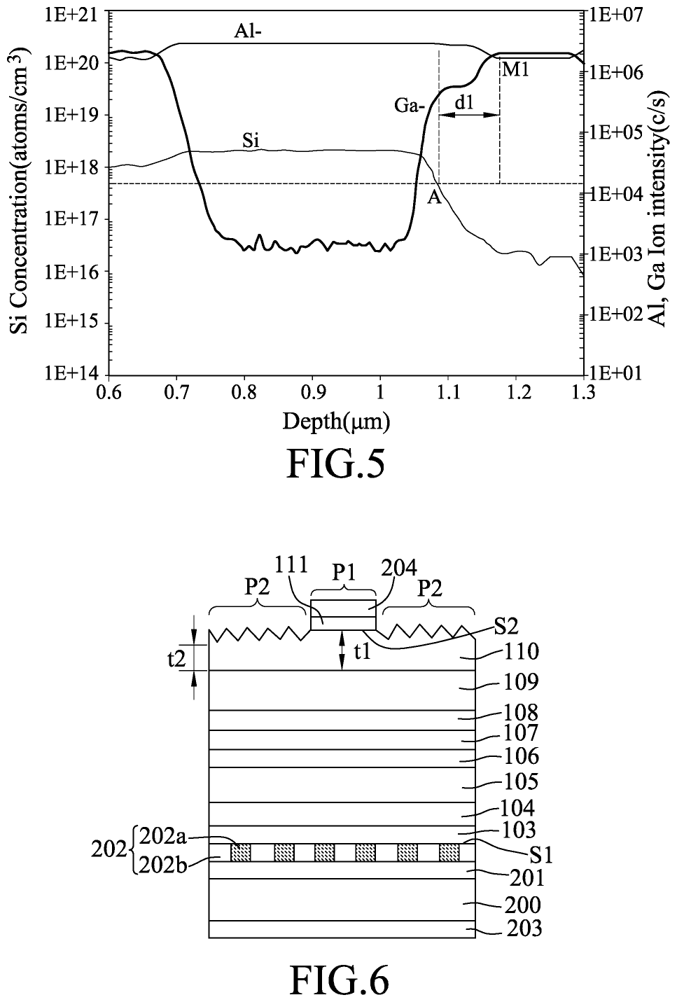

FIG. 5 is a graph illustrating a relationship between concentration or ion intensity and depth in a region of an embodiment of the semiconductor epitaxial structure of the disclosure. This embodiment is substantially the same as the embodiment shown in FIG. 1 except that, in this embodiment, the n-type dopant is Si. FIG. 5 was obtained from a secondary ion mass spectrometer, and shows the doping concentration of the n-type dopant and the relative ion intensity of Ga and Al. In this embodiment, the aluminum content has a relative ionic concentration profile. The lower surface (M1) of the active layer 107 corresponds to the position of the first valley of the relative ionic concentration profile of aluminum. The semiconductor epitaxial structure includes the n-type dopant, Si, disposed below the lower surface (M1) of the active layer 107 (i.e., in the first semiconductor layer), which has the doping concentration of 5E17/cm³ at the first point (A) in the first semiconductor layer. The distance from the first point (A) of the first semiconductor layer to the lower surface (M2) of the active layer 107 is defined to be the first distance (d1). In this embodiment, when the n-type dopant is Si, the first distance (d1) ranges from 150 nm to 300 nm. In other embodiments, the first distance (d1) ranges from 160 nm to 300 nm or 180 nm to 300 nm, so as to control diffusion of the dopant, Si, into the active layer 107, thereby improving the lattice quality of the active layer 107, and the luminous intensity and efficiency of the light-emitting device.

In this embodiment, the first cladding layer 105 may have a single-layered structure, and the first cladding layer 105 has a doping concentration greater than 5E17/cm³. In some embodiments, the doping concentration of the first cladding layer 105 is greater than 1E18/cm³, so as to provide sufficient electrons. The first cladding layer 105 includes a material that is represented by Alₓ₁Ga₁₋ₓ₁InP, wherein 0.4≤x1<1. In some embodiments, the first cladding layer 105 is made of AlInP. Since the intrinsic wavelength of the AlInP is 490 nm, light absorption of the first cladding layer 105 may be reduced, thereby improving the luminous intensity of the light-emitting device.

To prevent the p-type dopant from diffusing into the active layer 107, in this embodiment, the second distance (d2) between the second point (B) in the second semiconductor layer, which has the p-type doping concentration of 1E17/cm³, and the upper surface (M2) of the active layer 107, may be adjusted to range from, e.g., 40 nm to 400 nm. In other embodiments, the second distance (d2) ranges from 60 nm to 400 nm, or from 80 nm to 400 nm, so that the diffusion of the p-type dopant into the active layer 107 may be effectively controlled, thereby improving the lattice quality of the active layer 107, and the luminous intensity of the light-emitting device.

In this embodiment, by adjusting the first distance (d1) and/or second distance (d2), the diffusion of the dopant(s) into the active layer 107 may be controlled, and the lattice quality of the active layer 107 may be improved, thereby improving the optoelectronic performance of the light-emitting device.

FIG. 6 is a schematic view illustrating an embodiment of a light-emitting device according to the disclosure, which includes any one of the aforesaid epitaxial structures. In this embodiment, the epitaxial structure of FIG. 1 is used as an example but is not limited thereto. The light-emitting device further includes a substrate 200, and a bonding layer 201 that bonds the semiconductor epitaxial structure to the substrate 200. The semiconductor epitaxial structure includes the first ohmic contact layer 103, the first current spreading layer 104, the first cladding layer 105, the first spacing layer 106, the active layer 107, the second spacing layer 108, the second cladding 109, the second current spreading layer 110, and the second ohmic contact layer 111 sequentially disposed in such order on the substrate 200.

The substrate 200 is a conductive substrate and may be made of silicon, silicon carbide, or metal. Examples of the metal include copper, tungsten, molybdenum, etc. In some embodiments, the substrate 200 has a thickness no smaller than 50 μm so as to provide sufficient mechanical strength to support the semiconductor epitaxial structure. In addition, to facilitate further mechanical processing of the substrate 200 after bonding the semiconductor epitaxial structure to the substrate 200, the substrate 200 may have a thickness that is no greater than 300 μm. In this embodiment, the substrate 200 is a copper substrate.

The light-emitting device further includes a second electrode 204 that is disposed on the second ohmic contact layer 111. The second electrode 204 and the second ohmic contact layer 111 form an ohmic contact to allow an electric current to pass therethrough. During formation of the light-emitting device, the second ohmic contact layer 111 is etched to maintain a portion of the second ohmic contact layer 111 located right below the second electrode 204. The second current spreading layer 110 includes two portions in a horizontal direction perpendicular to the direction from the first surface (S1) to the second surface (S2): a first portion (P1) that is located right below the second ohmic contact layer 111 and the second electrode 204, and a second portion (P2) that is not located right below the second electrode 204. The second portion (P2) has a light-exiting surface that is not covered by and exposed from the second ohmic contact layer 111 and the second electrode 204. The light-exiting surface may surround the second electrode 204 and be a patterned surface or a roughened surface obtained via etching. The roughened surface may have a regular or an arbitrarily irregular micro/nanostructure. The light-exiting surface that is patterned or roughened facilitates an exit of light, so as to increase the luminous efficiency of the light-emitting device. In some embodiments, the light-exiting surface is a roughened surface that has a roughened structure with a height difference (between the highest and lowest point of the roughened structure) of less than 1 μm, e.g., from 10 nm to 300 nm.

Of the second current spreading layer 110, the first portion (P1) has a contact surface that is in contact with the second ohmic contact layer 111. The contact surface is not roughened because the contact surface is protected by the second electrode 204. The roughened surface of second portion (P2) of the second current spreading layer 110 is relatively lower than the contact surface of the first portion (P1) on a horizontal level.

Specifically, as shown in FIG. 6, in this embodiment, the first portion (P1) has a first thickness (t1). The second portion (P2) includes a base and a plurality of protrusions formed on the base, and the base has a second thickness (t2). In certain embodiments, the first thickness (t1) ranges from 1.5 μm to 2.5 μm, and the second thickness (t2) ranges from 0.5 μm to 1.5 μm. The first thickness (t1) of the first portion (P1) is greater than the second thickness (t2) of the second portion (P2). In some embodiments, the first thickness (t1) is greater than the second thickness (t2) by at least 0.3 μm.

The light-emitting device may further include a mirror layer 202 that is disposed between the semiconductor epitaxial structure and the substrate 200. The mirror layer 202 includes an ohmic contact metal sublayer 202a and a dielectric sublayer 202b. On one hand, the ohmic contact metal sublayer 202a and the dielectric sublayer 202b cooperate with the first ohmic contact layer 103 to form an ohmic contact. On the other hand, the ohmic contact metal sublayer 202a and the dielectric sublayer 202b reflect the light emitted by the active layer 107 toward the light-exiting surface of the second current spreading layer 110 or a side wall of the semiconductor epitaxial structure so as to facilitate the exit of light.

The light-emitting device further includes a first electrode 203. In some embodiments, the first electrode 203 may be disposed on the substrate 200 at a side where the semiconductor epitaxial structure is disposed or at a side opposite to the semiconductor epitaxial structure.

Each of the first electrode 203 and the second electrode 204 may be made of a transparent conductive material or a metal material. When each of the first electrode 203 and the second electrode 204 is made of a transparent conductive material, each of the first electrode 203 and the second electrode 204 is formed as a transparent conductive layer. The transparent conductive material may be indium tin oxide (ITO) or indium zinc oxide (IZO). The metal material may be GeAuNi, AuGe, AuZn, Au, Al, Pt, and Ti, and combinations thereof.

To improve reliability of the light-emitting device, the light-emitting device is provided with an insulation layer (not shown in the figure) on a surface and a side wall thereof. The insulation layer may have a single-layered or multilayered structure, and includes at least one of SiO₂, SiNₓ, Al₂O₃, and Ti₃O₅.

By adjusting the first distance (d1) between the first point (A) in the first semiconductor layer, which has the n-type doping concentration of 5E17/cm³, and the lower surface (M1) of the active layer 107, the diffusion of the n-type dopant into the active layer 107 may be controlled so as to improve the lattice quality of the active layer 107, thereby improving the photoelectric performance of the light-emitting device. At the same time, by further adjusting the second distance (d2) between the second point (B) in the second semiconductor layer, which has the p-type doping concentration of 1E17/cm³, and the upper surface (M2) of the active layer 107, the diffusion of the p-type dopant into the active layer 107 may be controlled so as to improve the lattice quality of the active layer 107, thereby improving the photoelectric performance of the light-emitting device.

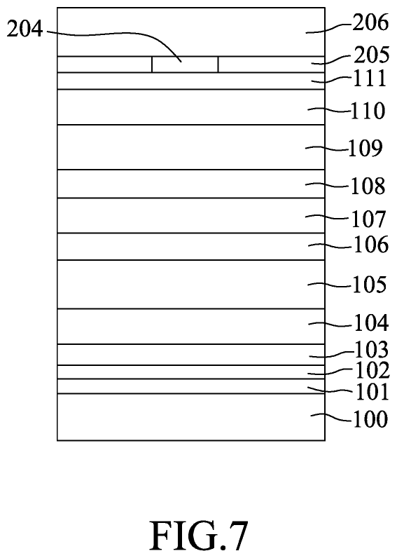

FIGS. 7 to 9 are schematic diagrams illustrating a method for manufacturing the light-emitting device shown in FIG. 6. Detailed descriptions are given below in connection with the schematic diagrams.

First, the semiconductor epitaxial structure as shown in FIG. 1 is provided. Specifically, the growth substrate 100 is provided, and the buffer layer 101, the etch stop layer 102 and the semiconductor epitaxial structure are grown on the growth substrate 100 using an epitaxy process, such as metal-organic chemical vapor deposition (MOCVD). The semiconductor epitaxial structure includes the first ohmic contact layer 103, the first current spreading layer 104, the first cladding layer 105, the first spacing layer 106, the active layer 107, the second spacing layer 108, the second cladding layer 109, the second current spreading layer 110, and the second ohmic contact layer 111 sequentially disposed in such order on the growth substrate 100.

Next, referring to FIG. 7, the second electrode 204 is formed on the second ohmic contact layer 111. A bonding adhesive 205 is used to bond the semiconductor epitaxial structure along with the second electrode 204 to a temporary substrate 206. In some embodiments, the bonding adhesive is a benzocyclobutene (BCB) adhesive, and the temporary substrate 206 is a glass substrate.

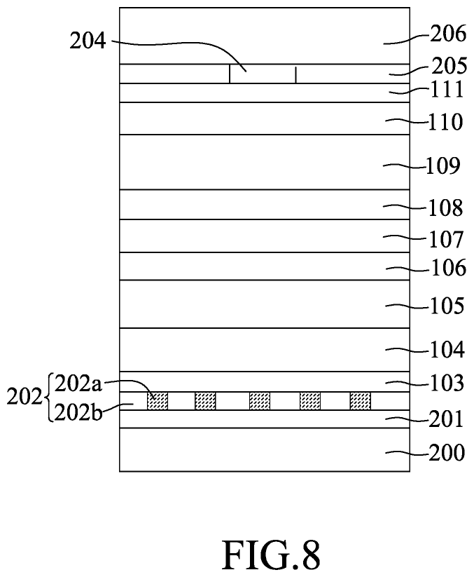

Next, wet etching is conducted to remove the growth substrate 100, the buffer layer 101, and the etch stop layer 102 so that the first ohmic contact layer 103 is exposed. The mirror layer 202 is then formed on the first ohmic contact layer 103, and includes the ohmic contact metal sublayer 202a and the dielectric sublayer 202b. On one hand, the ohmic contact metal sublayer 202a and the dielectric sublayer 202b cooperate to form an ohmic contact with the first ohmic contact layer 103. On the other hand, the ohmic contact metal sublayer 202a and the dielectric sublayer 202b reflect light emitted by the active layer 107. Next, the substrate 200 is provided. A metal bonding layer 201 is provided on the substrate 200 to bond the substrate 200 and the mirror layer 202 together, so as to obtain a structure as shown in FIG. 8.

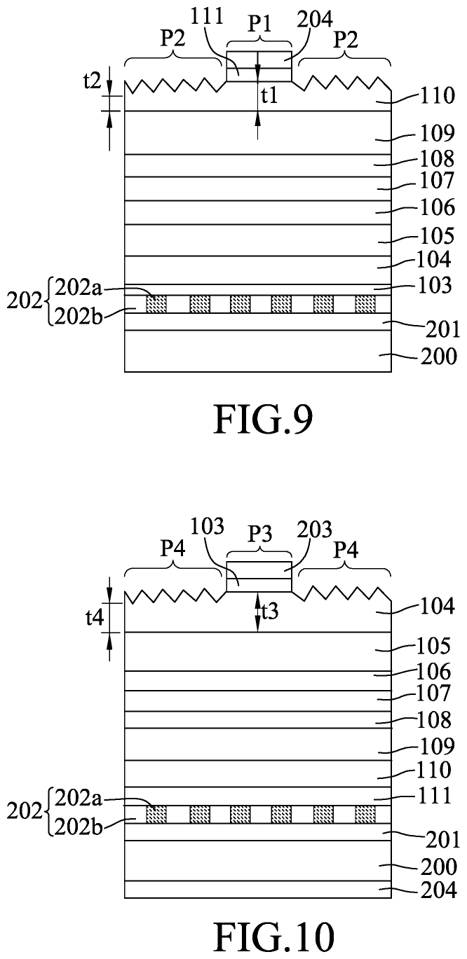

Then, wet etching is conducted to remove the temporary substrate 206 and the bonding adhesive 205. A mask (not shown) is provided to cover the second electrode 204, and a portion of the second ohmic contact layer 111 that is not covered by and surrounds the second electrode 204 is left exposed (i.e., not covered by the mask). Next, etching is performed to remove the portion of the second ohmic contact layer 111 that is left exposed, so that the second current spreading layer 110 is revealed. Afterwards, the second current spreading layer 110 is etched to form the patterned or roughened surface as shown in FIG. 9. It should be noted that the removal of the second ohmic contact layer 111 and the roughening of the second current spreading layer 110 may be conducted by wet etching in one step or multiple steps. Solutions used for wet etching may be acidic, such as hydrochloric acid, sulfuric acid, hydrofluoric acid, citric acid, or other chemical reagents.

Finally, the first electrode 203 is formed on the substrate 200 at the side opposite to the semiconductor epitaxial structure. Depending on requirements, processes such as etching or dicing are performed to obtain a plurality of unitized light-emitting devices, as shown in FIG. 6.

FIG. 10 illustrates a schematic view of another embodiment of the light-emitting device according to the disclosure, which includes any one of the aforesaid epitaxial structure. The epitaxial structure of FIG. 1 is used as an example in this embodiment, but is not limited thereto. The light-emitting device includes the substrate 200, the semiconductor epitaxial structure and the bonding layer 201 that bonds the semiconductor epitaxial structure to the substrate 200, and that includes the second ohmic contact layer 111, the second current spreading layer 110, the second cladding layer 109, the second spacing layer 108, the active layer 107, the first spacing layer 106, the first cladding layer 105, the first current spreading layer 104, and the first ohmic contact layer 103.

The substrate 200 is a conductive substrate and may be made of silicon, silicon carbide, or metal. Examples of the metal include copper, tungsten, molybdenum, etc. In some embodiments, the substrate 200 has a thickness no smaller than 50 μm so as to have sufficient mechanical strength to support the semiconductor epitaxial structure. In addition, to facilitate further mechanical processing of the substrate 200 after bonding the substrate 200 to the semiconductor epitaxial structure, the substrate 200 may have a thickness that is no greater than 300 μm. In this embodiment, the substrate 200 is a silicone substrate.

The first electrode 203 is disposed on the first ohmic contact layer 103. The first electrode 203 and the first ohmic contact layer 103 form an ohmic contact to allow an electric current to pass therethrough. During formation of the light-emitting device, the first ohmic contact layer 103 is etched to maintain a portion of the first ohmic contact layer 103 located right below the first electrode 203. The first current spreading layer 104 includes two portions in a horizontal direction perpendicular to the direction from the first surface (S1) to the second surface (S2): a third portion (P3) that is located right below the first ohmic contact layer 103 and the first electrode 203, and a fourth portion (P4) that is not located right below the first electrode 203. The fourth portion (P4) has a light-exiting surface that is not covered by and exposed from the first ohmic contact layer 103 and the first electrode 203. The light-exiting surface may surround the first electrode 203 and be a patterned surface or a roughened surface obtained via etching. The roughened surface may have a regular or an arbitrarily irregular micro/nanostructure. The light-exiting surface that is patterned or roughened facilitates an exit of light, so as to increase the luminous efficiency of the light-emitting device. In some embodiments, the light-exiting surface is a roughened surface that has a roughened structure with a height difference (between the highest and lowest point of the roughened structure) of less than 1 μm, e.g., from 10 nm to 300 nm.

Of the first current spreading layer 104, the third portion (P3) has a contact surface that is in contact with the first ohmic contact layer 103. The contact surface is not roughened because the contact surface is protected by the first electrode 203. The roughened surface of fourth portion (P4) of the first current spreading layer 104 is relatively lower than the contact surface of the third portion (P3) on a horizontal level.

Specifically, as shown in FIG. 10, in this embodiment, the third portion (P3) has a third thickness (t3). The fourth portion (P4) includes a base and a plurality of protrusions formed on the base, and the base has a fourth thickness (t4). In certain embodiments, the third thickness (t3) ranges from 1.5 μm to 2.5 μm, and the fourth thickness (t4) ranges from 0.5 μm to 1.5 μm. The third thickness (t3) of the third portion (P3) is greater than the fourth thickness (t4) of the fourth portion (P4). In some embodiments, the third thickness (t3) is greater than the fourth thickness (t4) by at least 0.3 μm.

The light-emitting device may further include the mirror layer 202 that is disposed between the semiconductor epitaxial structure and the substrate 200. The mirror layer 202 includes a p-type ohmic contact metal sublayer 202a and the dielectric sublayer 202b. On one hand, the p-type ohmic contact metal sublayer 202a and the dielectric sublayer 202b cooperate with the second ohmic contact layer 110 to form an ohmic contact. On the other hand, the p-type ohmic contact metal sublayer 202a and the dielectric sublayer 202b reflect the light emitted by the active layer 107 toward the light-exiting surface of the first current spreading layer 104 or the side wall of the semiconductor epitaxial structure so as to facilitate the exit of light.

The light-emitting device further includes the second electrode 204. In some embodiments, the second electrode 204 is disposed on the substrate 200 at the side where the semiconductor epitaxial structure is disposed or at the side opposite to the semiconductor epitaxial structure.

Each of the first electrode 203 and the second electrode 204 may be made of a transparent conductive layer or a metal material. When each of the first electrode 203 and the second electrode 204 is made of a transparent conductive material, each of the first electrode 203 and the second electrode 204 is formed as a transparent conductive layer. The transparent conductive material may be indium tin oxide (ITO) or indium zinc oxide (IZO). The metal material may be GeAuNi, AuGe, AuZn, Au, Al, Pt, and Ti, and combinations thereof.

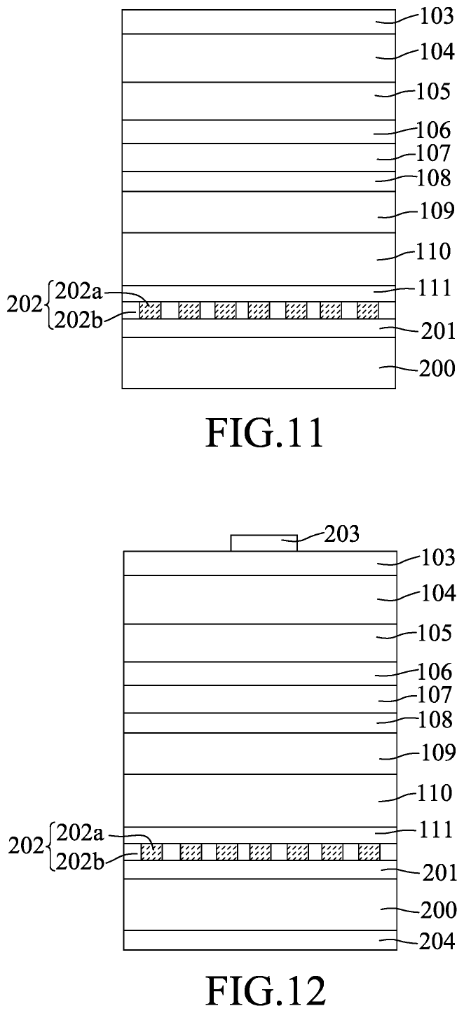

FIGS. 11 to 12 are schematic diagrams illustrating a method for manufacturing the light-emitting device as shown in FIG. 10. Detailed descriptions are given below in connection with the schematic diagrams.

First, the semiconductor epitaxial structure as shown in FIG. 1 is provided. Specifically, the growth substrate 100 is provided, and the buffer layer 101, the etch stop layer 102 and the semiconductor epitaxial structure are grown on the growth substrate 100 using an epitaxy process, such as metal-organic chemical vapor deposition (MOCVD). The semiconductor epitaxial structure includes the first ohmic contact layer 103, the first current spreading layer 104, the first cladding layer 105, the first spacing layer 106, the active layer 107, the second spacing layer 108, the second cladding layer 109, the second current spreading layer 110, and the second ohmic contact layer 111 sequentially disposed in such order on the growth substrate 100.

Next, the semiconductor epitaxial structure is transferred onto the substrate 200 and the growth substrate 100 is removed, so as to obtain a structure as shown in FIG. 11. Specifically, the mirror layer 202 is formed on the second ohmic contact layer 111, and includes the ohmic contact metal sublayer 202a and the dielectric sublayer 202b. On one hand, the ohmic contact metal sublayer 202a and the dielectric sublayer 202b cooperate to form an ohmic contact with the second ohmic contact layer 111. On the other hand, the ohmic contact metal sublayer 202a and the dielectric sublayer 202b reflect light emitted by the active layer 107. Next, the substrate 200 is provided, the metal bonding layer 201 is provided on the substrate 200 to bond the substrate 200 and the mirror layer 202 together, and the growth substrate 100 is removed. When the growth substrate 100 is made of GaAs, wet etching may be conducted for removing of the growth substrate 100 until the first ohmic contact layer 103 is revealed.

Next, referring to FIG. 12, the first electrode 203 is formed on the first ohmic contact layer 103, and a good ohmic contact is established between the first electrode 203 and the first ohmic contact layer 103. The second electrode 204 is formed on the substrate 200 at a side opposite to the semiconductor epitaxial structure, thereby providing current to flow through the first electrode 203, the second electrode 204, and the semiconductor epitaxial structure. The substrate 200 has a certain thickness so as to provide sufficient mechanical strength to support the semiconductor epitaxial structure.

Then, a mask (not shown) is provided to cover the first electrode 203, and a portion of the first ohmic contact layer 103 that is not covered by and surrounds the first electrode 203 is left exposed (i.e., not covered by the mask). Next, etching is performed to remove the portion of the first ohmic contact layer 103 that is left exposed, so that the first current spreading layer 104 is revealed. Afterwards, the first current spreading layer 104 is etched to form the patterned or roughened surface as shown in FIG. 9. It should be noted that the removal of the first ohmic contact layer 103 and the roughening of the first current spreading layer 104 may be conducted by wet etching in one step or multiple steps. Solutions used for wet etching may be acidic, such as hydrochloric acid, sulfuric acid, hydrofluoric acid, citric acid, or other chemical reagents.

Finally, depending on requirements, processes such as etching or dicing are performed to obtain a plurality of unitized light-emitting devices.

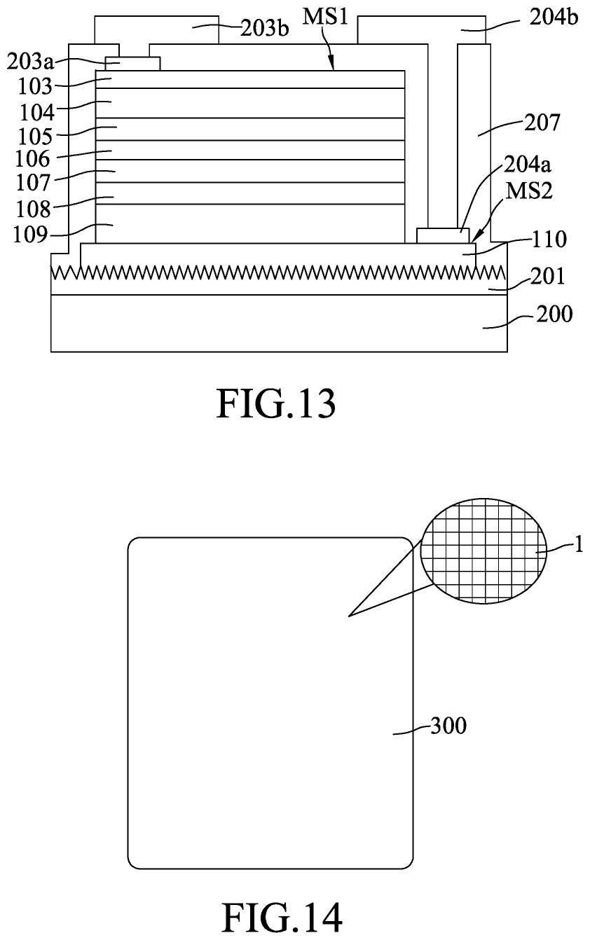

FIG. 13 shows an embodiment of the light-emitting device according to the disclosure, which has a flip-chip structure. Referring to FIG. 13, the light-emitting device includes the substrate 200, which may be a transparent substrate. In this embodiment, the substrate 200 is a sapphire substrate. The semiconductor epitaxial structure is bonded to the substrate 200 by the bonding layer 201, which is a transparent bonding layer. The semiconductor epitaxial structure includes a first mesa surface (MS1) and a second mesa surface (MS2). The second mesa surface (MS2) is formed by a recessed second semiconductor layer. The first electrode 203 includes a first ohmic contact portion 203a and a first pad electrode portion 203b. The second electrode 204 includes a second ohmic contact portion 204a and a second pad electrode portion 204b. The first ohmic contact portion 203a and the second ohmic contact portion 204a are disposed respectively on the first mesa surface (MS1) and the second mesa surface (MS2), so as to form an ohmic contact with the first semiconductor layer and the second semiconductor layer, respectively. A surface of the second current spreading layer 110 may have a roughened structure so as to facilitate the bonding layer 201 to be bonded to the semiconductor epitaxial structure, thereby bonding the semiconductor epitaxial structure and the substrate 200 together.

Referring to FIG. 14, an embodiment of a light-emitting apparatus 300 according to the disclosure is provided and includes a plurality of the light-emitting devices as described in any one of the previous embodiments. The light-emitting devices are arranged in an array. In FIG. 14, a portion of the light-emitting devices is enlarged and schematically shown.

In this embodiment, the light-emitting apparatus 300 may be a plant lighting device, a projector, a stage light, a display screen, etc.

Due to including the light-emitting devices as described in any one of the previous embodiments, the light-emitting apparatus 300 offers advantages of the light-emitting devices of the aforementioned embodiments.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cladding various arrangements included within the spirit and scope of the broadest interpretation so as to encompass all such modifications and equivalent arrangements.

What is claimed is:

1. A light-emitting device, comprising:
a semiconductor epitaxial structure that has a first surface and a second surface opposite to said first surface, and that includes a first semiconductor layer, an active layer, and a second semiconductor layer sequentially disposed in such order in a direction from said first surface to said second surface, said active layer including well layers and barrier layers that are alternately stacked, said active layer having an upper surface that is adjacent to said second semiconductor layer and a lower surface that is opposite to said upper surface,
wherein said first semiconductor layer is doped with an n-type dopant, said n-type dopant having a first concentration of 5E17/cm³ at a first point in said first semiconductor layer, said first point of said first semiconductor layer and said lower surface of said active layer having a first distance therebetween, said first distance ranging from 150 nm to 500 nm.

2. The light-emitting device as claimed in claim 1, wherein said n-type dopant contains Si, Ge, Sn, Te, or combinations thereof.

3. The light-emitting device as claimed in claim 1, wherein said n-type dopant contains Te and said first distance ranges from 200 nm to 500 nm.

4. The light-emitting device as claimed in claim 3, wherein said first semiconductor layer includes a first cladding layer, said first cladding layer including a first sublayer and a second sublayer, said first sublayer having a doping concentration no smaller than 8E17/cm³, said second sublayer having a concentration that gradually decreases in the direction from said first surface of said semiconductor epitaxial structure to said second surface of said semiconductor epitaxial structure.

5. The light-emitting device as claimed in claim 4, wherein said first sublayer has a thickness that is one-third to two-thirds of a thickness of said first cladding layer.

6. The light-emitting device as claimed in claim 1, wherein said n-type dopant contains Si and said first distance ranges from 150 nm to 300 nm.

7. The light-emitting device as claimed in claim 6, further comprising a first cladding layer, said first cladding layer having a doping concentration no smaller than 5E17/cm³.

8. The light-emitting device as claimed in claim 7, wherein said first cladding layer is made of AlGaInP.

9. The light-emitting device as claimed in claim 7, further comprising a first spacing layer disposed between said first cladding layer and said active layer, said first spacing layer being made of AlGaInP.

10. The light-emitting device as claimed in claim 9, wherein said first spacing layer has a single layered structure or a multilayered structure.

11. The light-emitting device as claimed in claim 10, wherein said first spacing layer has the multilayered structure, said first spacing layer having an aluminum content that first decreases and then remains constant in the direction from said first surface of said semiconductor epitaxial structure to said second surface of said semiconductor epitaxial structure.

12. The light-emitting device as claimed in claim 1, wherein said second semiconductor layer is doped with a p-type dopant, said p-type dopant having a second concentration of 1E17/cm³ at a second point in said second semiconductor layer, said second point of said second semiconductor layer and said upper surface of said active layer having a second distance therebetween, said second distance ranging from 40 nm to 400 nm.

13. The light-emitting device as claimed in claim 1, wherein said second semiconductor layer includes a second cladding layer and a second spacing layer, said second spacing layer being disposed between said active layer and said second cladding layer.

14. The light-emitting device as claimed in claim 13, wherein said second spacing layer is made of AlGaInP and has a doping concentration no greater than 1E17/cm³.

15. The light-emitting device as claimed in claim 13, wherein said second spacing layer has a thickness no greater than 400 nm.

16. The light-emitting device as claimed in claim 12, wherein said p-type dopant contains Mg, Zn, Ca, Sr, Ba, or combinations thereof.

17. The light-emitting device as claimed in claim 1, wherein each of said well layers and a corresponding one of said barrier layers that is adjacent to said each of said well layers constitute a layer unit, a number of layer unit ranging from 2 to 100.

18. The light-emitting device as claimed in claim 1, wherein each of said well layers has a thickness ranging from 2 nm to 25 nm, and each of said barrier layers has a thickness ranging from 2 nm to 25 nm.

19. The light-emitting device as claimed in claim 1, wherein said active layer emits light having a wavelength ranging from 550 nm to 950 nm.

20. A light-emitting apparatus comprising the light-emitting device as claimed in claim 1.
